(19) United States
(12) Patent Application Publication
(10) Pub. No.: US 2025/0183069 A1
(43) Pub. Date: Jun. 5, 2025

(54) CONFIGURABLE AND MODULAR LOAD LOCK CHAMBER SYSTEMS AND METHODS OF MAKING LOAD LOCKS FOR SEMICONDUCTOR PROCESSING SYSTEMS

(71) Applicant: ASM IP Holding B.V., Almere (NL)

(72) Inventor: Samer Banna, Phoenix, AZ (US)

(21) Appl. No.: 18/961,256

(22) Filed: Nov. 26, 2024

Related U.S. Application Data
(60) Provisional application No. 63/604,691, filed on Nov. 30, 2023.

(51) Int. Cl. H01L 21/67

(52) U.S. Cl. CPC H01L 21/67201

(57) ABSTRACT

A load lock arrangement includes a load lock body that has an upper plate defining an upper accessory seat at the upper accessory seat aperture, an intermediate plate spaced apart from the upper plate defining an intermediate accessory seat at the intermediate accessory seat aperture, and a lower plate separated from the upper plate by the intermediate plate defining a lower accessory seat at the lower accessory seat aperture. A first accessory plate is fixed to the upper accessory seat and a second accessory plate is fixed to the lower accessory seat. The upper accessory seat aperture, the intermediate accessory seat aperture and the lower accessory seat aperture are vertically aligned to form a load lock body aperture. Semiconductor processing systems and methods of making load lock arrangements are also described.

### CROSS-REFERENCE TO RELATED APPLICATION(S)

This application claims the benefit of U.S. Provisional Application 63/604,691 filed on Nov. 30, 2023, the entire contents of which are incorporated herein by reference.

### FIELD OF INVENTION

The present disclosure generally relates to fabricating semiconductor devices. More particularly, the present disclosure relates to load lock arrangements for semiconductor processing systems employed to fabricate semiconductor devices.

### BACKGROUND OF THE DISCLOSURE

Semiconductor processing systems, such as semiconductor processing systems with cluster-type platforms, commonly include a front-end connected to a back-end by a load lock. The front-end generally interfaces the semiconductor processing system to the external environment and typically includes a front-end robot to transfer substrates between the front-end of the semiconductor processing system and the load lock. The back-end typically includes a process module wherein substrate processing is accomplished and a back-end robot to transfer substrates between the load lock and the process module. The load lock generally couples the back-end of the semiconductor processing system to the front-end of the semiconductor processing system and is typically arranged to isolate the environment maintained in the back-end of the semiconductor processing system to the environment maintained in the front-end of the semiconductor processing system.

One challenge to load locks is the need to incorporate different types of accessories within the load lock to facilitate substrate processing in the semiconductor processing system. For example, a heating arrangement may be incorporated in the load lock for heating substrates prior to transferring into the process module, improving system throughout by limiting the time required for temperature ramping in the process module. A cooling arrangement may be incorporate into the load lock for cooling substrates prior to transfer from the process module into the load lock, limiting time required to ramp the substrates from the desired material layer deposition temperature subsequent to material layer deposition. This can also improve system throughput by reducing the time that a substrate may remain in the process module subsequent to material layer deposition. Incorporation of substrate heating and substrate cooling in load locks generally requires that the load lock have a customized configuration corresponding to substrate heating and/or substrate cooling requirements of the process performed in the process module coupled to the load lock. Further, conventional semiconductor processing systems have one of two types of load lock arrangements: 1) accommodate a single wafer at a time or 2) accommodate a batch wafer (i.e. cassette of wafers, for example, 25 wafers at a time).

However, conventional systems require a different load lock chamber for each processing operation depending on the requirements of the given processing operation. That is, if a given processing operation is different from the previous processing operation, the load lock may need to be replaced with one having an accessory not originally included in the load lock so that it can support the given processing operation. Thus, each time a processing operation differs from a previous one, a new load lock chamber may be required. Such customization of load locks can complicate redeployment and/or reuse of semiconductor processing system.

Accordingly, there is a need in the art for improved load lock arrangements, semiconductor processing systems having load lock arrangements, material layer deposition methods, and methods of making load lock arrangements for semiconductor processing systems. The present disclosure provides a solution to this need.

### SUMMARY OF THE DISCLOSURE

A load lock arrangement is provided. The load lock arrangement includes a load lock body having an upper plate having an upper accessory seat aperture and defining an upper accessory seat at the upper accessory seat aperture; an intermediate plate spaced apart from the upper plate having an intermediate accessory seat aperture and defining an intermediate accessory seat at the intermediate accessory seat aperture; a lower plate separated from the upper plate by the intermediate plate having a lower accessory seat aperture and defining a lower accessory seat at the lower accessory seat aperture. A first accessory plate is fixed to the upper accessory seat; and second accessory plate is fixed to the lower accessory seat. The upper accessory seat aperture, the intermediate accessory seat aperture and the lower accessory seat aperture are vertically aligned to form a load lock body aperture.

A method of making a load lock arrangement is provided. The method includes a load lock chamber body having an upper plate having an upper accessory seat aperture and defining an upper accessory seat at the upper accessory seat aperture, an intermediate plate spaced apart from the upper plate having an intermediate accessory seat aperture and defining an intermediate accessory seat at the intermediate accessory seat aperture, and a lower plate separated from the upper plate by the intermediate plate having a lower accessory seat aperture and defining a lower accessory seat at the lower accessory seat aperture. The method further includes determining a processing operation of a process module, wherein the process module is coupled to a back-end transfer module, and wherein the back-end transfer module is coupled to the load lock chamber body. When the processing operation is determined to require substrate cooling in at least one chamber of the load lock chamber, the method includes fixing a chill plate to at least one of the upper accessory seat, the lower accessory seat and the intermediate accessory seat. When the processing operation is determined to require substrate heating in at least one chamber of the load lock chamber, method includes fixing a heater plate to at least one of the upper accessory seat, the lower accessory seat and the intermediate accessory seat.

A semiconductor processing system is provided. The system includes a process module; a back-end transfer module connected to the process module and housing a back-end substrate transfer robot; and a load lock arrangement connected to the back-end transfer module and further connected to an equipment front-end module housing a front-end substrate transfer robot. The load lock arrangement further comprises a load lock chamber body having: an upper plate having an upper accessory seat aperture and defining an upper accessory seat at the upper accessory seat aperture; an intermediate plate spaced apart from the upper plate having an intermediate accessory seat aperture and defining an intermediate accessory seat at the intermediate accessory seat aperture; a lower plate separated from the upper plate by the intermediate plate having a lower accessory seat aperture and defining a lower accessory seat at the lower accessory seat aperture; a first accessory plate fixed to the upper accessory seat; and a second accessory plate fixed to the lower accessory seat, The upper accessory seat aperture, the intermediate accessory seat aperture and the lower accessory seat aperture are vertically aligned to form a load lock body aperture. The front-end substrate transfer robot and the back-end substrate transfer robot are configured to transfer substrates between the equipment front-end module and the process module through the load lock body chamber.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a plan view of a semiconductor processing system with a load lock arrangement in accordance with the present disclosure, schematically showing the load lock arrangement coupling an equipment front-end module to a process module;

FIGS. 2A and 2B are top and sectional views of the load lock arrangement of FIG. 1, schematically showing front-end gave valves and back-end gate valves spaced apart from one another by upper and lower plate members of the load lock, respectively;

FIG. 3 is sectional view of the load lock arrangement of FIG. 1 shown for atomic layer deposition (ALD) process modules;

FIG. 4 is a sectional view of the load lock arrangement of FIG. 1 shown for process modules that require substrate cooling within a lower chamber defined in the load lock body;

FIG. 5 is a sectional view of the load lock arrangement of FIG. 1 shown for a six facet platform, that may require cooling in an upper chamber and/or a lower chamber of load lock chamber body;

FIG. 6 is a sectional view of the load lock arrangement of FIG. 1 shown for accommodation of multiple wafer substrates; and

FIG. 7 is a block diagram of a method for making a load lock arrangement for a semiconductor processing system according to the present disclosure.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

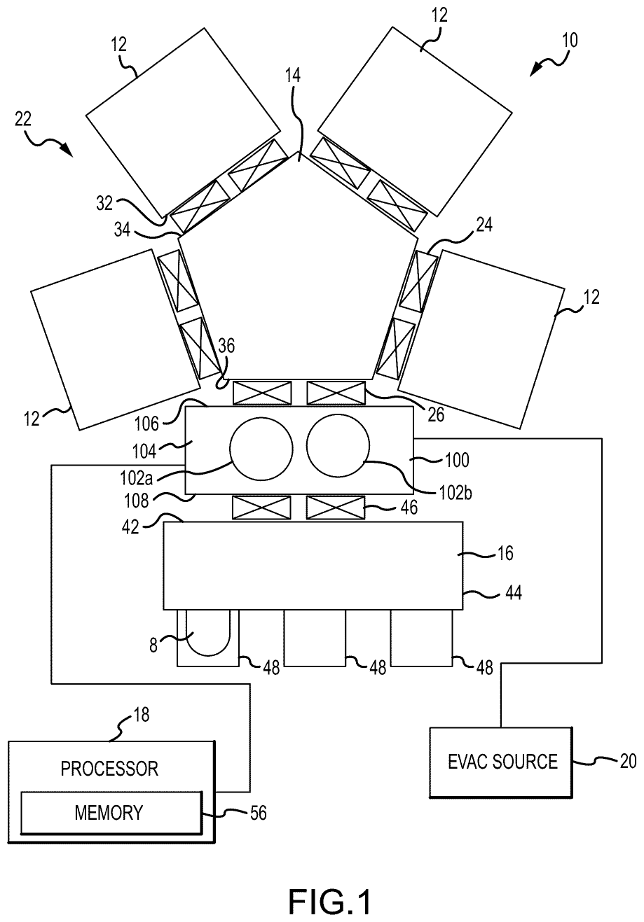

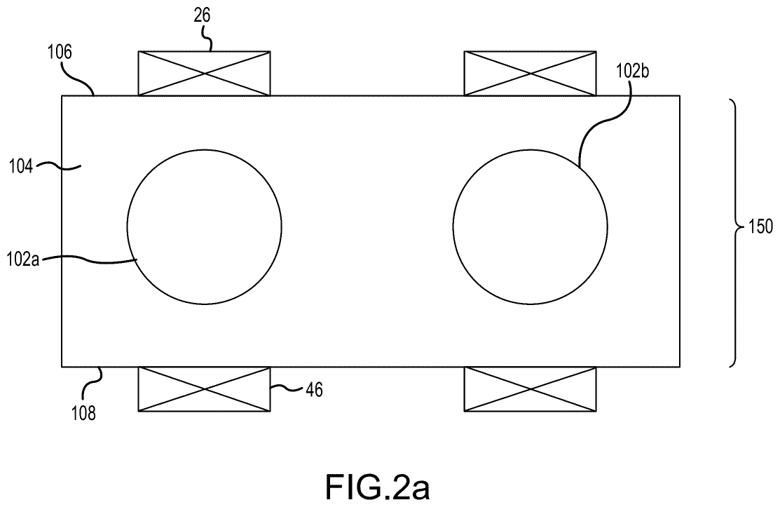

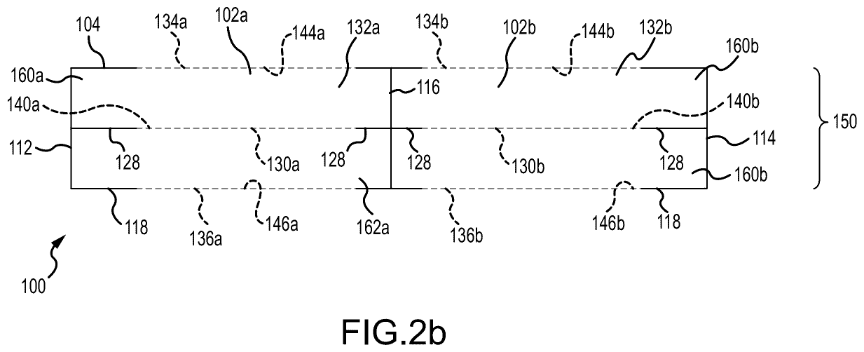

Reference will now be made to the drawings wherein like reference numerals identify similar structural features or aspects of the subject disclosure. For purposes of explanation and illustration, and not limitation, a partial view of a load lock arrangement coupling a process module to an equipment front-end module (EFEM) of a semiconductor processing system in accordance with the present disclosure is shown in FIG. 1 and is designated generally by reference character 100. Other examples of load lock arrangements, semiconductor processing systems having load lock arrangements, material layer deposition methods, and methods of making load lock arrangements in accordance with the present disclosure, or aspects thereof, are provided in FIGS. 2-7, as will be described. The systems and methods of the present disclosure may be in semiconductor processing systems employed to fabricate semiconductor devices, such as in semiconductor processing systems employed to deposit material layers using chemical vapor deposition (CVD) and atomic layer deposition (ALD) techniques during the fabrication of logic and memory devices, though the present disclosure is not limited to any semiconductor processing operation or to the fabrication of any particular semiconductor device in general.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Wafers may be 200 millimeters in diameter, 300 millimeters, or even 450 millimeters in diameter. Substrates may be formed from one or more semiconductor materials including by way of non-limiting example silicon, silicon germanium, silicon oxide, gallium arsenide, gallium nitride and silicon carbide.

Referring to FIG. 1, a semiconductor processing system 10 is shown. The semiconductor processing system 10 includes at least one process module 12, a back-end transfer module 14, and the load lock arrangement 100. The semiconductor processing system 10 also includes an equipment front-end module (EFEM) 16, a processor 18, and an evacuation source 20. In the illustrated example, the semiconductor processing system 10 includes a cluster-type platform 22 with four (4) process modules configured to deposit a material layer onto a substrate using an atomic layer deposition (ALD) technique. This is for illustration and description purposes only and is non-limiting. As will be appreciated by those of skill in the art in view of the present disclosure, semiconductor processing systems configured for other material layer deposition operations as well as semiconductor processing systems configured for processing operations other than material layer deposition can also benefit from the present disclosure.

At least one process module 12 is coupled to the back-end transfer module 14 by at least one process module gate valve 24. In some examples, process module 12 may include a second process module gate valve that also couples process module 12 to back-end transfer module 14. Process module 12 further includes at least one process chamber. In some examples, process module 12 may include more than one process chamber. The process chamber(s) may be configured to flow a material layer precursor or reactant across the substrate during deposition of a material layer onto the substrate. A reactant source may be fluidly coupled to the process chamber of the process module to provide the reactant to the process chamber for deposition of the material layer on to the substrate.

Process module 12 includes a process module facet 32 that is parallel to one of the back-end transfer facets 34. Accordingly, process module 12 is coupled to a process module gate valve 24 at process module facet 32, and process module gate valve 24 is coupled to back-end transfer module 14 at back-end transfer module facet 34. Thus, process module 12 is coupled to the back-end transfer module 14 using process module gate valve 24, which is configured to provide selective communication between the process chamber of process module 12 and the back-end transfer module 14. It is contemplated that the process module gate valve 24 be configured to permit transfer of the substrate between the back-end transfer module 14 and the process module 12 before and after deposition of the material layer onto the substrate. In certain examples, the material layer may be deposited using an ALD or a CVD deposition technique. In some examples, the material layer may be deposited using a plasma enhanced ALD (PEALD) or a plasma enhanced CVD (PECVD) technique.

The back-end transfer module 14 is coupled to the load lock arrangement 100 and includes a back-end chamber body and a back-end substrate transfer robot. The back-end transfer module 14 is further coupled to the load lock arrangement 100 via back-end gate valve 26. In certain example embodiments, back-end gate valve 26 is similar to process module gate valve 24. In that, back-end gate valve 26 may be configured to permit transfer of one or more substrates between the load lock arrangement 100 and back-end transfer module 14. As shown in FIG. 1, load lock arrangement 100 includes load lock arrangement back-end facet 106. Back-end gate valve 26 is coupled to load lock arrangement 100 at load lock arrangement back-end facet 106, and back-end valve 26 is further coupled to back-end transfer module 14 at back-end transfer module facet 36. Accordingly, load lock arrangement 100 is coupled to back-end transfer module 14 using back-end gate valve 26, which is configured to provide selective communication between the back-end transfer module 14 and a load lock chamber of load lock arrangement 100. In example embodiments, load lock arrangement back-end facet 106 is arranged in a parallel configuration with back-end transfer module facet 36.

In example embodiments, back-end chamber body of back-end transfer module is a polygonal shape. In the embodiment shown in FIG. 1, back-end chamber body of back-end transfer module 14 has five sides, wherein four of the sides include back-end transfer module facet 34 that couple back-end transfer module 14 to at least one process module 12, and wherein the fifth side includes back-end transfer module facet 36 that couples the back-end transfer module 36 to load lock arrangement 100. In other example embodiments, back-end chamber body may have more than five sides or less than five sides, and may have shape of a regular or irregular polygon.

The load lock arrangement 100 is further coupled to the EFEM 16 via load lock gate valve 46. In certain example embodiments, load lock gate valve 46 is similar to back-end gate valve 26. In that, load lock gate valve 46 may be configured to permit transfer of one or more substrates between the load lock arrangement 100 and EFEM 16. EFEM 16 further includes an enclosure 44 that houses a front-end substrate transfer robot, which is configured to move within enclosure 44 for transfer of substrates between one or more load ports 48 and the load lock arrangement 100. The one or more load ports 48 included within EFEM 16 is connected to enclosure 44 and is configured to seat a pod 8 housing one or more substrates prior to and subsequent to deposition of material layers onto the substrates. In the example shown in FIG. 1, EFEM 16 includes three load ports 48. However, in other examples, EFEM 16 may include fewer or additional load ports.

A processor 18 is coupled to the semiconductor processing system 10, for example, through (or over) a wired or wireless link. The processor 18 is operably connected to a user interface and is disposed in communication with a memory 56. The memory 56 includes a non-transitory machine-readable medium having a plurality of program modules recorded thereon containing instructions that, when read by the processor 52, cause the processor to execute certain operations.

As has been explained above, some semiconductor processing systems require substrate heating and/or substrate cooling within the system load lock, such as for throughput purposes. For example, in some semiconductor processing systems, substrate heating within the system load lock may be required to limit processing time within the process module to shorten the time required to ramp substrate temperature to a desired material layer deposition temperature. Alternatively or additionally, substrate cooling within the system load locks may be required to limit processing time within the system process modules to limit time otherwise required for substrate cooling in the process modules following material layer deposition. Conventional semiconductor processing systems don't allow changes in load lock configuration in a modular fashion. For example, configuration of load lock chamber to meet requirements for substrate cooling are different from the requirements for substrate heating. Accordingly, if a semiconductor processing system houses a load lock chamber configured for substrate cooling, to switch to a heating configuration, such a load lock chamber would first have to be removed and a new load lock chamber configured to meet requirement for substrate heating would have to be fitted. Load lock arrangement 100 provided herein alleviates this issue by providing a load lock chamber that can accommodate multiple configurations in a single design.

With reference to FIG. 2a, a load lock arrangement 100 is shown in a top view. As shown in FIG. 2a, the load lock arrangement 100 includes a load lock chamber body 150, a load lock gate valve 46, and a back-end gate valve 26. As shown in FIG. 2a, back-end gate valve 26 is connected to load lock arrangement 100 at back-end wall (at the back end facet 106) and load lock gate valve 46 is connected to load lock arrangement 100 at front-end wall (at the front-end facet 108). The load lock chamber body 150 further includes an upper plate 104. In the example shown in FIG. 2a, load lock chamber body 150 further includes two apertures 102a and 102b.

With reference now to FIG. 2b, a cross-sectional view of load lock arrangement 100 is shown. As shown in FIG. 2b, load lock chamber body 150 includes a first sidewall 112 and a second sidewall 114. Further, load lock chamber body 150 includes an upper plate 104 and a lower plate 118. Upper plate 104 and Lower plate 118 connect with the first sidewall 112, and upper plate 104 and lower plate 118 connect with the second sidewall 114 to form load lock chamber body 150. That is, upper plate 104, lower plate 118, first sidewall 112 and second sidewall 114 together form the outer perimeter of load lock chamber body 150.

In example embodiments, load lock chamber body 150 further includes a divider wall 116 that divides load lock chamber body 150 into two different chambers 132a and 132b. Similar to first sidewall 112 and second sidewall 114, divider wall 116 connects with upper plate 104 and lower plate 118 to form two chambers 132a and 132b, respectively. In example embodiments, load lock chamber 150 further includes at least one intermediate plate to further divide load lock chamber 150 into a top chamber and a bottom chamber. As shown in FIG. 2b, intermediate plate 128 couples with first sidewall 112 and second sidewall 114 to facilitate formation of an upper left chamber and bottom left chamber. Indeed, intermediate plate 128 is arranged below upper plate 104 and above lower plate 118, and is coupled to upper plate 104 and lower plate 118 by the front-end wall (including front-end facet 108), the back-end wall (including back-end facet 106), the first sidewall 112, and the second sidewall 114. The upper plate 104 is spaced apart from the intermediate plate 128 by an upper chamber 160 and the lower plate 118 is spaced apart from the intermediate plate 128 by a lower chamber 162. In example embodiments, space between upper plate 104 and intermediate plate 128 is the same as the space between intermediate plate 128 and lower plate 118. In the exemplary embodiment shown in FIG. 2a, load lock chamber body 150 further includes a divider wall 116 that divides load lock chamber body 150 into two chambers 132a and 132b. Consequently, similar to sidewalls 112 and 114, intermediate plate 128 is coupled to divider wall 116.

As shown in FIG. 2a, upper plate 104 includes at least one upper accessory seat aperture 134 and defines an upper accessory seat 144 that is configured to accommodate various types of fixations. Similarly, intermediate plate 128 includes at least one intermediate accessory seat aperture 130 and defines an intermediate accessory seat 140 that is configured to accommodate various types of fixations. Further, lower plate 118 includes at least one lower accessory seat aperture 136 and defines a lower accessory seat 146 that is configured to accommodate various types of fixations. Upper accessory seat aperture 134, intermediate accessory seat aperture 130 and lower accessory seat aperture 136 align vertically to form aperture 102 through load lock chamber body 150.

In certain examples, upper accessory seat 144 may be a first upper accessory seat 144a and the upper plate 104 may further include a second upper accessory aperture 134b to define a second upper accessory seat 144b. The second upper accessory seat 144b may be similar to the first upper accessory seat 144a and additionally may be laterally offset from the first upper accessory seat 144a, for example, on a side of the divider wall 116 (shown in FIG. 2a) opposite that of the first upper accessory seat 144a.

Similarly, in certain examples, intermediate accessory seat 140 may be a first intermediate accessory seat 140a and the intermediate plate 128 may further include a second intermediate accessory aperture 130b to define a second intermediate accessory seat 140b. The second intermediate accessory seat 140b may be similar to the first intermediate accessory seat 140a and additionally may be laterally offset from the first intermediate accessory seat 140a, for example, on a side of the divider wall 116 (shown in FIG. 2a) opposite that of the first intermediate accessory seat 140a.

Further, in certain examples, lower accessory seat 146 may be a first lower accessory seat 146a and the lower plate 118 may further include a second lower accessory aperture 136b to define a second lower accessory seat 146b. The second lower accessory seat 146b may be similar to the first lower accessory seat 146a and additionally may be laterally offset from the first lower accessory seat 146a, for example, on a side of the divider wall 116 (shown in FIG. 2a) opposite that of the first lower accessory seat 146a.

In certain such examples, first upper aperture 134a, intermediate aperture 130a and lower apertures 136a vertically align to form an aperture 102a through load lock chamber 150. Similarly, second upper, intermediate and lower accessory apertures 134b, 130b, and 136b vertically align to form an aperture 102b through load lock chamber 150. These apertures (102a and 102b) may be covered by an accessory piece that is chosen based on requirements of the processing operation.

In certain examples, load lock chamber body 150 may be formed in a monolithic manner. That is, the intermediate plate 128, one or more front-end wall (including front-end facet 108), one or more back-end wall (including back-end facet 106), first sidewall 112, second sidewall 114, divider wall 116, upper plate 104 and lower plate 118 may be formed from a common piece of stock. In this respect, a portion of the load lock body 100 including the intermediate plate 128 may be formed from a common piece of stock using a subtractive technique, and the upper plate 104 fixed using fasteners or welding. In further respect the portion of load lock body 150 may be formed using an additive technique and the upper plate 104 fixed to the intermediate plate 128 through the one or more of the front-end wall, the back-end wall, the first sidewall 112, and the second sidewall 114.

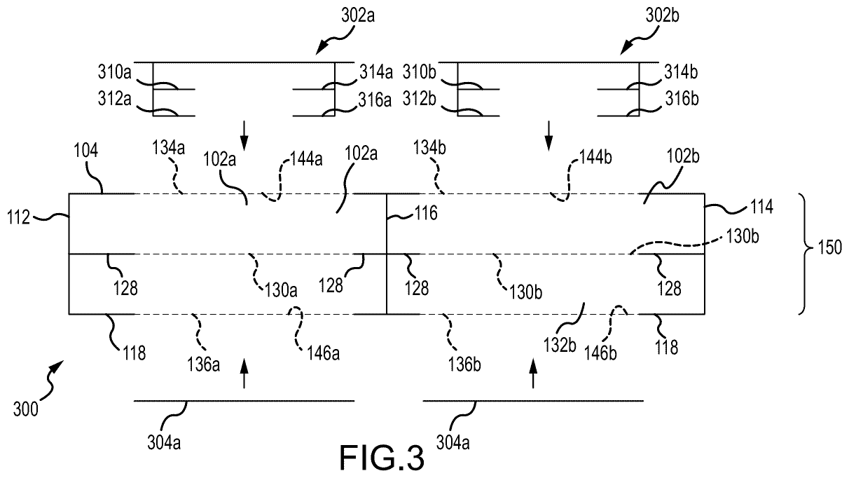

Referring now to FIG. 3, a cross-section view of an example load lock arrangement 300 is shown for ALD process modules. The load lock chamber body 150 shown in FIG. 3A is similar to the load lock chamber body of FIG. 2A. In this particular embodiment, heating and cooling of the substrates is not required in the load lock chamber body 150 during transfer. Accordingly, at least one of the upper accessory aperture 134 and lower accessory aperture 136 may be covered with a blanking plate 304 to fluidly isolate the load lock chamber body 150 from an external environment outside of the load lock chamber body 150. In the example shown herein, the first lower aperture 136 of the load lock chamber body 150 may be covered with a blanking plate 304 and fluidly separate the lower chamber of the load lock chamber body 150 from an external environment outside of the load lock chamber body. Blanking plate 304 is received by load lock chamber body 150 at the lower accessory seat 146. A gasket or sealing member may be compressively fixed between the lower plate 118 and blanking plate 304 to isolate the lower chamber 162 from external environment.

In certain examples, upper aperture 144 may also be covered with a blanking plate, such as a blanking plate 304 and is affixed at the upper accessory seat 134 in a manner similar to affixation at the lower accessory seat 146. However, in the example shown herein, a substrate support plate 302 is received at the upper accessory seat 134 and cover upper accessory aperture 134. Substrate support plate 302 is configured to support a substrate within the upper chamber 160 of load lock chamber body 150. As shown in FIG. 3a, substrate support plate 302 includes at least four fingers 310, 312, 314 and 316, and a substrate received in upper chamber 160 may be supported within the fingers 310, 312, 314 and 316.

In certain examples, blanking plate 304 may be a first blanking plate 304a that covers the first lower accessory aperture 136a at a first lower accessory seat 146a, and substrate support plate 302 may be a first substrate support plate 302a that covers the first upper accessory aperture 134a at a first upper accessory seat 144a. Blanking plate 304 may further include a second blanking plate 304b that covers the second lower accessory aperture 136b at the second lower accessory seat 146b, and substrate support plate 302 may include a second substrate support plate 302b that covers the second upper accessory aperture 134b at the second upper accessory seat 144b. Although the load lock arrangement 300 is shown and described herein as having particular arrangements, it is to be understood and appreciated that the load lock arrangement may have a different arrangement is other examples and remain within the scope of the present disclosure.

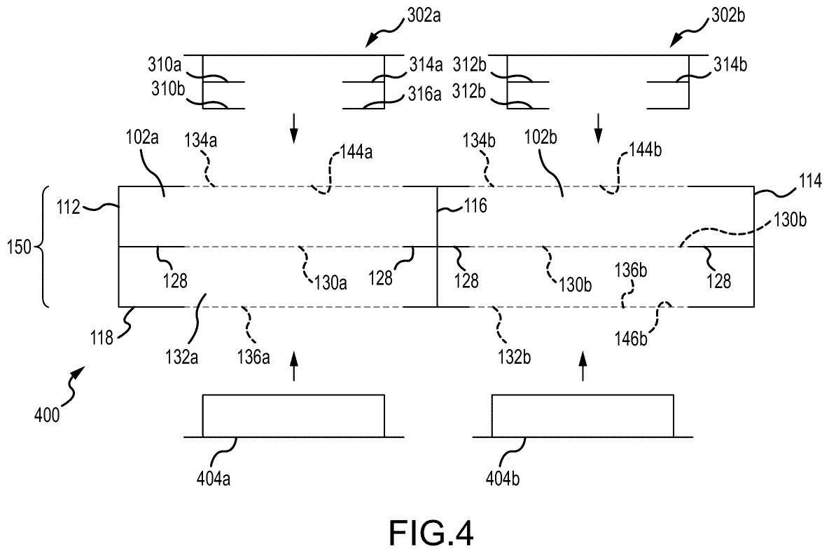

Referring to FIG. 4, a cross-section view of an example load lock arrangement 400 is shown for process modules that require substrate cooling within the lower chamber 162 of load lock chamber body 150. The load lock chamber body 150 shown in FIG. 4A is similar to the load lock chamber body of FIG. 2A. Load lock arrangement 400 is similar to load lock arrangement 300 of FIG. 3A. However, because processing operation requires substrate cooling in the load lock chamber body 150, a chill plate is fixed to at least one of the upper accessory seat 144, intermediate accessory seat 140 and lower accessory seat 146.

In the example embodiment shown in FIG. 4, a lower chill plate 404 is fixed to lower accessory seat 146 and covers lower accessory aperture 136. In the example shown in FIG. 4, intermediate accessory aperture 130 remains uncovered. Accordingly, a lower chill plate 404 fixed to lower accessory seat 146 may be configured to cool a substrate supported within chamber defining aperture 102. Cooling may be accomplished, for example, by convection by introducing a fluid between the substrate and an upper surface of the lower chill plates 404a and 404b.

In certain examples, lower chill plate 404 may be a first lower chill plate 404a that covers the first lower accessory aperture 136a at a first lower accessory seat 146a. Lower chill plate 404 may further include a second lower chill plate 404b that covers the second lower accessory aperture 136b at a second lower accessory seat 146b. The second lower chill plate 404b may be similar to the first lower chill plate 404a. In accordance with certain examples, the second lower accessory seat 146b (and the second lower chill plate 404b) may be laterally separated from the first lower accessory seat 146a (and the first lower chill plate 404a) to provide symmetrical cooling of the substrates supported above the first lower chill plate 404a and second lower chill plate 404b using fluid issued from the first lower chill plate 404a and the second lower chill plate 404b.

As shown in FIG. 4, substrate support plate 302a covers the first upper accessory aperture 134a at a first upper accessory seat 144a, and substrate support plate 302b covers the second upper accessory aperture 134b at a second upper accessory seat 144b. Accordingly, substrate support plates 302a and 302b remain unchanged from the configuration in FIG. 3 to the configuration in FIG. 4. Indeed, as shown in FIG. 4, chill plates 404a and 404b are configured to cool one ore more substrates supported by substrate support plates 302a and 302b, respectively. Thus, changes in the processing operation does not require a change of the entire load lock chamber body. Rather, only the lower accessory must be replaced to accommodate the change in processing operation.

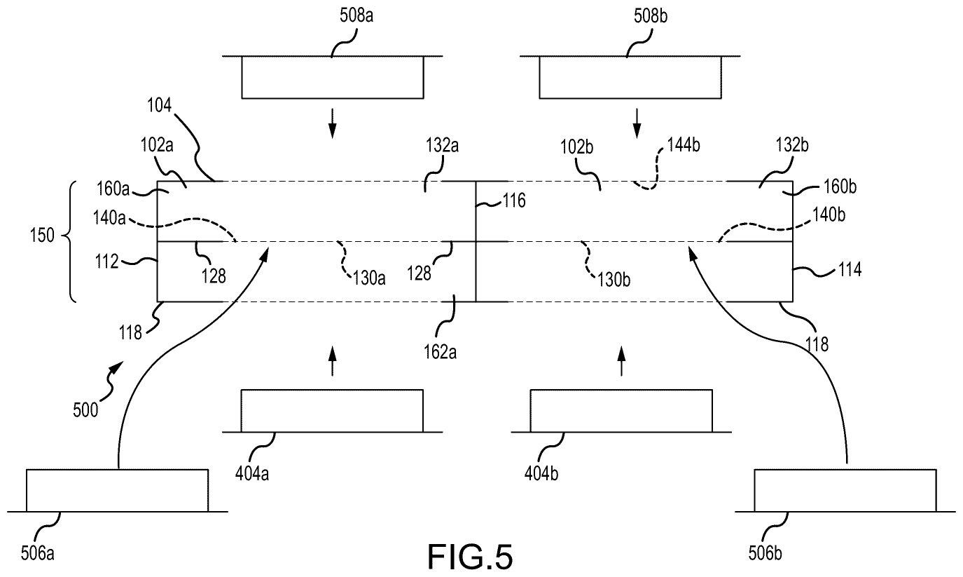

Referring now to FIG. 5, a cross-section view of an example load lock arrangement 500 is shown for a six facet platform. In the exemplary embodiment shown in FIG. 5, processing operation requires cooling in an upper chamber and a lower chamber of load lock chamber body 150. Accordingly, as shown in FIG. 5, a chill plate is fixed to at least two of the upper accessory seat 144, intermediate accessory seat 140 and lower accessory seat 146.

As will be appreciated by those of skill in the art in view of present disclosure the load lock arrangement 100 may include other elements and/or omit certain illustrated elements and remain within the scope of the present disclosure. As will be appreciated by those of skill in the art in view of present disclosure the load lock arrangement 100 may include other elements and/or omit certain illustrated elements and remain within the scope of the present disclosure.

In certain examples, the lower chill plate shown in FIG. 5 may be the same as the lower chill plate shown in FIG. 4. Accordingly, lower chill plate 404 covers lower accessory aperture 136 and is fixed to lower accessory seat 146. Similar to FIG. 4, in certain examples, lower chill plate 404 may be a first lower chill plate 404a that covers the first lower accessory aperture 136a at a first lower accessory seat 146a. Lower chill plate 404 may further include a second lower chill plate 404b that covers the second lower accessory aperture 136b at a second lower accessory seat 146b. The second lower chill plate 404b may be similar to the first lower chill plate 404a. In accordance with certain examples, the second lower accessory seat 146b (and the second lower chill plate 404b) may be laterally separated from the first lower accessory seat 146a (and the first lower chill plate 404a) to provide symmetrical cooling of the substrates supported above the first lower chill plate 404a and second lower chill plate 404b using fluid issued from the first lower chill plate 404a and the second lower chill plate 404b.

Load lock arrangement 500 further includes an intermediate chill plate 506. As shown in FIG. 5, intermediate chill plate 506 is fixed to intermediate accessory seat 140 and covers intermediate accessory aperture 130. Intermediate chill plate 506 functions in a manner similar to lower chill plate 404. In certain examples, intermediate chill plate 506 may be a first intermediate chill plate 506a that covers the first intermediate accessory aperture 130a at a first intermediate accessory seat 140a. intermediate chill plate 506 may further include a second intermediate chill plate 506b that covers the second intermediate accessory aperture 130b at a second intermediate accessory seat 140b. The second intermediate chill plate 506b may be similar to the first intermediate chill plate 506a. In accordance with certain examples, the second intermediate accessory seat 140b (and the second lower chill plate 506b) may be laterally separated from the first intermediate accessory seat 140a (and the first intermediate chill plate 506a) to provide symmetrical cooling of the substrates supported above the first intermediate chill plate 506a and second intermediate chill plate 506b using fluid issued from the first intermediate chill plate 506a and the second intermediate chill plate 506b.

In certain examples, load lock arrangement 500 further includes an upper chill plate 508. As shown in FIG. 5, upper chill plate 508 is fixed to upper accessory seat 144 and covers intermediate accessory aperture 132. Upper chill plate 508 functions in a manner similar to lower chill plate 404. In certain examples, upper chill plate 508 may be a first upper chill plate 508a that covers the first upper accessory aperture 134a at a first upper accessory seat 144a. intermediate chill plate 508 may further include a second upper chill plate 508b that covers the second upper accessory aperture 134b at a second upper accessory seat 144b. The second upper chill plate 508b may be similar to the first upper chill plate 508a. In accordance with certain examples, the second upper accessory seat 144b (and the second upper chill plate 508b) may be laterally separated from the first upper accessory seat 144a (and the first upper chill plate 508a) to provide symmetrical cooling of the substrates supported above the first upper chill plate 508a and second upper chill plate 508b using fluid issued from the first upper chill plate 508a and the second upper chill plate 508b.

As shown in FIG. 5, intermediate accessory apertures 130a and 130b are covered by fixing intermediate chill plates 506a and 506b to intermediate accessory seats 140a and 140b, respectively. Upper accessory apertures 134a and 134b are covered by fixing upper chill plates 508a and 508b to upper accessory seats 144a and 144b, respectively. And lower accessory apertures 136a and 136b are covered by fixing lower chill plates 404a and 404b to lower accessory seats 146a and 146b, respectively. Consequently, as shown in FIG. 5, at least two upper chambers 160a and 160b, and at least two lower chambers 162a and 162b are formed in load lock chamber body 150. Thus, load lock arrangement 500 meets the requirements for substrate cooling within the upper chambers 160a and 160b, and lower chambers 162a and 162b.

In one alternative example embodiment, load lock arrangement 500 may include intermediate chill plates 506a and 506b fixed to intermediate accessory seats 140a and 140b, lower chill plates 404a and 404b fixed to lower accessory seats 146a and 146b, respectively, and blanking plates 304a and 304b (as shown in FIG. 3) fixed to upper accessory seats 144a and 144b, respectively. Such an alternative load lock arrangement 500 would also meet requirements for substrate cooling within upper chambers 160a and 160b, and lower chambers 162a and 162b.

In another alternative example embodiment, load lock arrangement 500 may include upper chill plates 508a and 508b fixed to upper accessory seats 144a and 144b, lower chill plates 404a and 404b fixed to lower accessory seats 146a and 146b, respectively, and blanking plates 304a and 304b (as shown in FIG. 3) fixed to intermediate accessory seats 140a and 140b, respectively. Such an alternative load lock arrangement 500 would also meet requirements for substrate cooling within upper chambers 160a and 160b, and lower chambers 162a and 162b.

Accordingly, load lock arrangement 500 enables easy conversion of the illustrated example of load lock arrangement 500 to any desired arrangement based on processing operation of process module(s) 12. Such an arrangement further facilitates conversion to an arrangement where substrate heating may be required in the upper chamber (160a, 160b) but not in the lower chambers (162a, 162b) by fixing blanking plates to the upper accessory seats (144a, 144b) and a heater to the intermediate accessory seats (140a, 140b), or vice versa. Similarly, such an arrangement also facilitates conversion to an arrangement where substrate heating may be required in the lower chamber (162a, 162b) but not in the upper chamber (160a, 160b) by fixing blanking plates to the lower accessory seats (144a, 144b) and a heater to the intermediate accessory seats (140a, 140b), and vice versa.

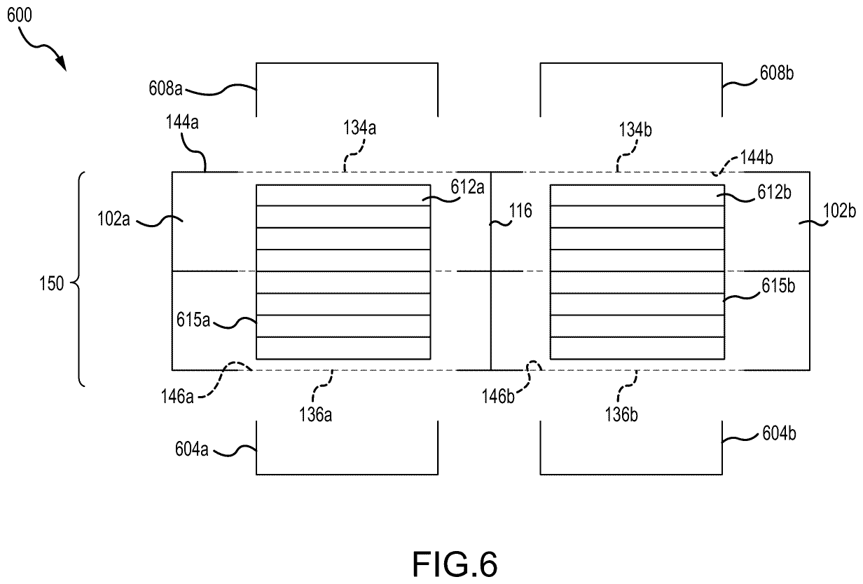

Referring now to FIG. 6, cross section view of load lock arrangement 600 is shown for accommodation of multiple wafer substrates at once. As shown in FIG. 6, load lock arrangement 600 includes a load lock chamber body 150 (as discussed in FIGS. 1-5). However, instead of a substrate support plate 302 (as shown in FIG. 3), load lock chamber body 150 is configured to accommodate multiple wafer substrates.

Load lock arrangement 600 includes an upper can 608 and a lower can 604. Upper can 608 and lower can 604 are configured to hold a quartz boat 615 in load lock chamber aperture 102. As shown in FIG. 6, upper can 608 covers upper accessory aperture 134 and is fixed to upper accessory seat 144a, and lower can 604 covers lower accessory aperture 136 and is fixed to lower accessory seat 146a. Upper can 608 and lower can 604 hold the quartz boat 615 such that it sits in the chamber defined by aperture 102 through load lock chamber body 150. Quartz boat 615 includes multiple slots 612, wherein each of the slots 612 is configured to hold one wafer substrate. Thus, one quartz boat 615 can hold multiple wafer substrates. In one exemplary embodiment, quartz boat 615 is configured to hold 25 wafer substrates. Accordingly, load lock arrangement 600 enables load lock chamber body 150 to accommodate multiple wafer substrates at once. Such an arrangement can be advantageous in time management when an extensive number of wafers have to be processed.

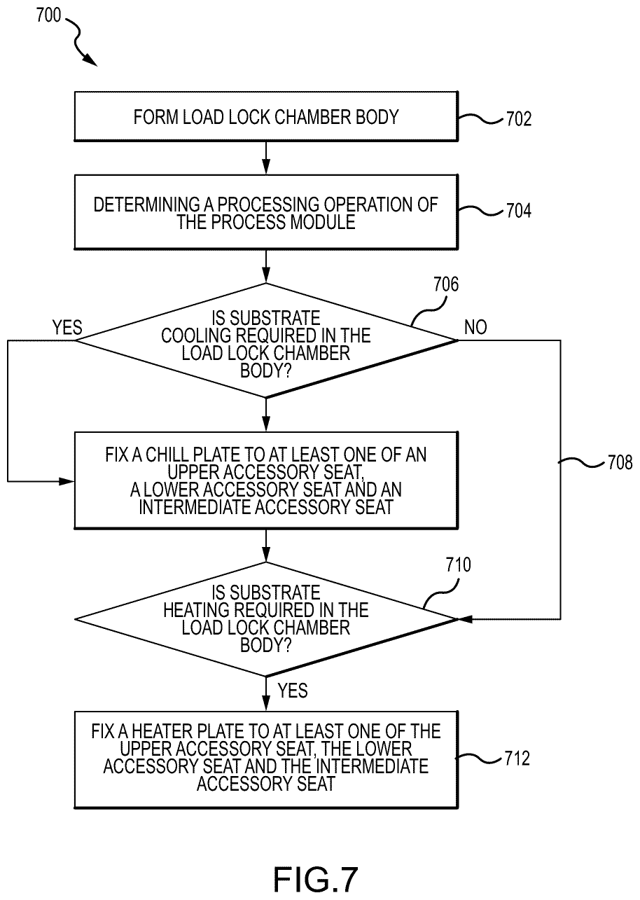

With reference to FIG. 7, a method 700 of making a load lock arrangement for a semiconductor processing system, e.g., the load lock arrangement 500 (shown in FIGS. 2A-2B). Step 702 of method 700 includes forming a load lock chamber body, e.g., the load lock chamber body 150 (shown in FIGS. 2A-2B). Step 704 of method 700 includes determining a processing operation of the process module. Step 706 of method 700 includes determining if substrate cooling is required within a chamber of the load lock chamber body. When it is determined that substrate cooling is required in one of the chambers of the load lock chamber body, step 708 of method 700 includes fixing a chill plate, e.g., chill plate 508 to at least one of an upper accessory seat, e.g., upper accessory seat 144, a lower accessory seat, e.g., lower accessory seat 146 and an intermediate accessory seat, e.g., intermediate accessory seat 140.

In exemplary embodiments of method 700, if substrate cooling is required, step 206 further comprises determining the chamber requiring substrate cooling. For example, when substrate cooling is required in an upper chamber, such as upper chamber 160 (shown in FIG. 5) of the load lock body, method 700 further comprises fixing the chill plate, e.g., chill plate 508 to one of the upper accessory seat and the intermediate accessory seat. When substrate cooling is required in a lower chamber, such as lower chamber 162 (shown in FIG. 5) of load lock chamber body, method 700 further comprises fixing the chill plate, e.g., chill plate 404 to one of the lower accessory seat and in the intermediate accessory seat.

Step 710 of method 700 includes determining if substrate heating is required within a chamber of the load lock chamber body. When it is determined that substrate heating is required in one of the chambers of the load lock chamber body, step 712 of method 700 includes fixing a heater plate to at least one of the upper accessory seat, the lower accessory seat and the intermediate accessory seat of the load lock chamber. For example, when heating is required in an upper chamber of load lock chamber body, method 700 includes fixing a heater plate to at least one of the upper accessory seat and the intermediate accessory seat to provide heat to the upper chamber. When heating is required in a lower chamber of load lock chamber body, method 700 includes fixing a heater plate to at least one of the intermediate accessory seat and the lower accessory seat to provide heat to the lower chamber.

In exemplary embodiments, method 700 further comprises fixing a substrate support plate to an upper accessory seat. In some exemplary embodiments, method 700 further comprises fixing an upper can to the upper accessory plate and fixing a lower can to the lower accessory plate. The upper and lower accessory plates couple together to hold a quartz boat, such as quartz boat 615 (see FIG. 6), which is configured to hold multiple substrates at once. In exemplary embodiments, when neither heating nor cooling is required, method 700 comprises fixing a blanking plate to at least one of an upper accessory seat, a lower accessory seat and an intermediate accessory seat.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A load lock arrangement, comprising:
a load lock body having:
an upper plate having an upper accessory seat aperture and defining an upper accessory seat at the upper accessory seat aperture;
an intermediate plate spaced apart from the upper plate having an intermediate accessory seat aperture and defining an intermediate accessory seat at the intermediate accessory seat aperture;
a lower plate separated from the upper plate by the intermediate plate having a lower accessory seat aperture and defining a lower accessory seat at the lower accessory seat aperture;
a first accessory plate fixed to the upper accessory seat; and
a second accessory plate fixed to the lower accessory seat,
wherein the upper accessory seat aperture, the intermediate accessory seat aperture and the lower accessory seat aperture are vertically aligned to form a load lock body aperture.

2. The load lock arrangement of claim 1, wherein at least one of the first accessory plate and the second accessory plate is a blanking plate.

3. The load lock arrangement of claim 2, wherein the first accessory plate is a substrate support plate and the second accessory plate is a blanking plate.

4. The load lock arrangement of claim 1, wherein at least one of the first accessory plate and the second accessory plate is a chill plate.

5. The load lock arrangement of claim 4, wherein the first accessory plate is a substrate support plate and the second accessory plate is a chill plate.

6. The load lock arrangement of claim 1, further comprising:
a third accessory plate fixed to the intermediate accessory seat.

7. The load lock arrangement of claim 6, wherein the third accessory plate is at least one of a blanking plate and a chill plate.

8. The load lock arrangement of claim 6,
wherein the second accessory plate is a chill plate; and
wherein at least one of the first accessory plate and the third accessory plate is a chill plate.

9. The load lock arrangement of claim 7,
wherein the second accessory plate is a chill plate;
wherein when the first accessory plate is a blanking plate, the third accessory plate is a chill plate; and
wherein when the first accessory plate is a chill plate, the third accessory plate is a blanking plate.

10. The load lock arrangement of claim 1,
wherein the first accessory plate is an upper can, wherein the second accessory plate is a lower can, and wherein the upper can and the lower can are coupled such that they hold a quartz boat within the load lock body aperture, and wherein the quartz boat is configured to hold multiple substrates.

11. The load lock arrangement of claim 1, wherein:
the upper plate further comprises a second upper accessory seat aperture defining a second upper accessory seat at the second upper accessory seat aperture;
the intermediate plate further comprises a second intermediate accessory seat aperture defining as second intermediate accessory seat at the second intermediate accessory seat aperture;
the lower plate further comprises a second lower accessory seat aperture defining a second lower accessory seat at the second lower accessory seat aperture; and
the load lock body further comprises:
a fourth accessory plate fixed to the second upper accessory seat; and
a fifth accessory plate fixed to the second lower accessory seat,
wherein the second upper accessory seat aperture, the second intermediate accessory seat aperture and the second lower accessory seat aperture are vertically aligned to form a second load lock body aperture.

12. The load lock arrangement of claim 11, wherein:
the fourth accessory plate is the same type of plate as the first accessory plate; and
the fifth accessory plate is the same type of plate as the second accessory plate.

13. The load lock arrangement of claim 12, further comprises:
a divider perpendicularly coupled to the upper plate and the lower plate such that the load lock chamber body is divided into a first chamber having the upper accessory seat and the lower accessory seat and a second chamber having the second upper accessory seat and the second lower accessory seat.

14. A method of making a load lock arrangement, comprising:
including a load lock chamber body having an upper plate having an upper accessory seat aperture and defining an upper accessory seat at the upper accessory seat aperture, an intermediate plate spaced apart from the upper plate having an intermediate accessory seat aperture and defining an intermediate accessory seat at the intermediate accessory seat aperture, and a lower plate separated from the upper plate by the intermediate plate having a lower accessory seat aperture and defining a lower accessory seat at the lower accessory seat aperture;
determining a processing operation of a process module, wherein the process module is coupled to a back-end transfer module, and wherein the back-end transfer module is coupled to the load lock chamber body;
when the processing operation is determined to require substrate cooling in at least one chamber of the load lock chamber, fixing a chill plate to at least one of the upper accessory seat, the lower accessory seat and the intermediate accessory seat; and
when the processing operation is determined to require substrate heating in at least one chamber of the load lock chamber, fixing a heater plate to at least one of the upper accessory seat, the lower accessory seat and the intermediate accessory seat.

15. The method of claim 14, further comprising fixing a blanking plate to at least one of the upper accessory seat, the lower accessory seat and the intermediate accessory seat.

16. The method of claim 14, further comprising fixing a substrate support plate to an upper accessory seat.

17. The method of claim 14, further comprising:
fixing an upper can to the upper accessory plate; and
fixing a lower can to the lower accessory plate such that the upper can is coupled to the lower can to hold a quartz boat within the load lock chamber body, and wherein the quartz boat is configured to hold multiples substrates.

18. A semiconductor processing system, comprising:
a process module;
a back-end transfer module connected to the process module and housing a back-end substrate transfer robot; and
a load lock arrangement connected to the back-end transfer module and further connected to an equipment front-end module housing a front-end substrate transfer robot,
wherein the load lock arrangement further comprises a load lock chamber body having:
an upper plate having an upper accessory seat aperture and defining an upper accessory seat at the upper accessory seat aperture;
an intermediate plate spaced apart from the upper plate having an intermediate accessory seat aperture and defining an intermediate accessory seat at the intermediate accessory seat aperture;
a lower plate separated from the upper plate by the intermediate plate having a lower accessory seat aperture and defining a lower accessory seat at the lower accessory seat aperture;
a first accessory plate fixed to the upper accessory seat; and
a second accessory plate fixed to the lower accessory seat,
wherein the upper accessory seat aperture, the intermediate accessory seat aperture and the lower accessory seat aperture are vertically aligned to form a load lock body aperture, and
wherein the front-end substrate transfer robot and the back-end substrate transfer robot are configured to transfer substrates between the equipment front-end module and the process module through the load lock body chamber.

19. The semiconductor processing system of claim 18, wherein at least one of the first accessory plate and the second accessory plate is configured to hold a single substrate in a single chamber of the load lock chamber body.

20. The semiconductor processing system of claim 18, wherein the first accessory plate and the second accessory plate are coupled together and further configured to hold a quartz boat, wherein the quartz boat is configured to hold multiple substrates in a single chamber of the load lock body.
